(19) United States
(12) Patent Application Publication
(10) Pub. No.: US 2026/0018485 A1
(43) Pub. Date: Jan. 15, 2026

(54) SEMICONDUCTOR UNIT

(71) Applicant: Mitsubishi Electric Corporation, Tokyo (JP)

(72) Inventor: Ryunosuke MATSUMOTO, Tokyo (JP)

(73) Assignee: Mitsubishi Electric Corporation, Tokyo (JP)

(21) Appl. No.: 19/186,442

(22) Filed: Apr. 22, 2025

(30) Foreign Application Priority Data
Jul. 11, 2024 (JP) 2024-111485

(51) Int. Cl. H01L 23/40; H01L 23/48

(52) U.S. Cl. CPC H01L 23/4006; H01L 23/48; H01L 2023/4031; H01L 2023/4062; H01L 2023/4087

(57) ABSTRACT

A semiconductor unit includes: a semiconductor module including a semiconductor device and a horizontal terminal; a base plate including an upper surface to which the semiconductor module is bonded and a plurality of screw holes passing through the base plate from the upper surface to a lower surface; a cooler attached to the lower surface of the base plate and cooling the semiconductor module; and a plurality of screws screwed to the plurality of screw holes of the base plate, respectively, so that the cooler is attached to the lower surface of the base plate. A spot facing part having a depth smaller than a thickness of the base plate is provided to a part of at least one of the plurality of screw holes on a side of the upper surface of the base plate.

### BACKGROUND

### Technical Field

The present disclosure relates to a semiconductor unit.

### Description of the Background Art

Generally, a semiconductor module such as an insulated gate bipolar transistor (IGBT) module, an intelligent power module (IPM), or a transfer-molded power module (T-PM) radiates heat caused by power loss, thus is connected to a cooler via a base plate to constitute a semiconductor unit (for example, refer to International Publication No. 2019/181198).

In attaching the base plate and the cooler using a screw, heat radiation properties, a torque in fastening the screw, an insulation distance from the screw as reference potential and a terminal having high voltage potential, and downsizing of the semiconductor unit needs to be considered.

### SUMMARY

However, in the conventional technique, ensuring of insulation properties between the screw for attaching the cooler and a horizontal terminal of the semiconductor module and downsizing of the semiconductor unit contradict each other; thus, it is difficult to achieve both of them.

An object of the present disclosure is to provide a technique capable of achieving both ensuring of insulation properties between a screw for attaching a cooler and a horizontal terminal of a semiconductor module and downsizing of a semiconductor unit.

A semiconductor unit according to the present disclosure includes at least one semiconductor module, a base plate, a cooler, and a plurality of screws. The semiconductor module includes a semiconductor device and at least one horizontal terminal electrically connected to the semiconductor device and protruding from at least one side surface in a horizontal direction. The base plate includes an upper surface to which the semiconductor module is bonded and a plurality of screw holes passing through the base plate from the upper surface to a lower surface. The cooler is attached to the lower surface of the base plate and cools the semiconductor module. The plurality of screws are screwed to the plurality of screw holes of the base plate, respectively. Thus, the cooler is attached to the lower surface of the base plate. A spot facing part having a smaller depth than a thickness of the base plate is provided to a part of at least one of the plurality of screw holes on a side of the upper surface of the base plate.

Both ensuring of insulation properties between a screw for attaching a cooler and a horizontal terminal of a semiconductor module and downsizing of a semiconductor unit can be achieved.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a perspective view illustrating a configuration of a semiconductor unit according to an embodiment 1.

FIG. 2 is a top view of the semiconductor device according to the embodiment 1.

FIG. 3 is a cross-sectional view of a position where a base plate and a cooler are fastened by a screw and a region around the position according to the embodiment 1.

FIG. 4 is a cross-sectional view of a position where a base plate and a cooler are fastened by a screw and a region around the position in a case where a spot facing part is not provided to a screw hole.

FIG. 5 is a top view of a semiconductor unit according to an embodiment 2.

FIG. 6 is a top view of a semiconductor unit according to an embodiment 3.

FIG. 7 is a top view of a semiconductor unit according to an embodiment 4.

FIG. 8 is a cross-sectional view of a position where a base plate and a cooler are fastened by a screw and a region around the position according to an embodiment 5.

FIG. 9 is a top view of a semiconductor unit according to an embodiment 6.

FIG. 10 is a top view of a semiconductor unit according to an embodiment 7.

FIG. 11 is a cross-sectional view of a position where a base plate and a cooler are fastened by a screw and a region around the position according to an embodiment 8.

FIG. 12 is a top view of a semiconductor unit according to an embodiment 10.

FIG. 13 is a top view of a semiconductor unit according to an embodiment 11.

FIG. 14 is a top view of a semiconductor unit in a case where the number of screw holes is the same in a side of a P or N electrode and a side of an AC electrode.

FIG. 15 is a top view of a semiconductor unit according to an embodiment 12.

FIG. 16 is a top view of a semiconductor unit according to an embodiment 13.

### DESCRIPTION OF THE PREFERRED EMBODIMENTS

### Embodiment 1

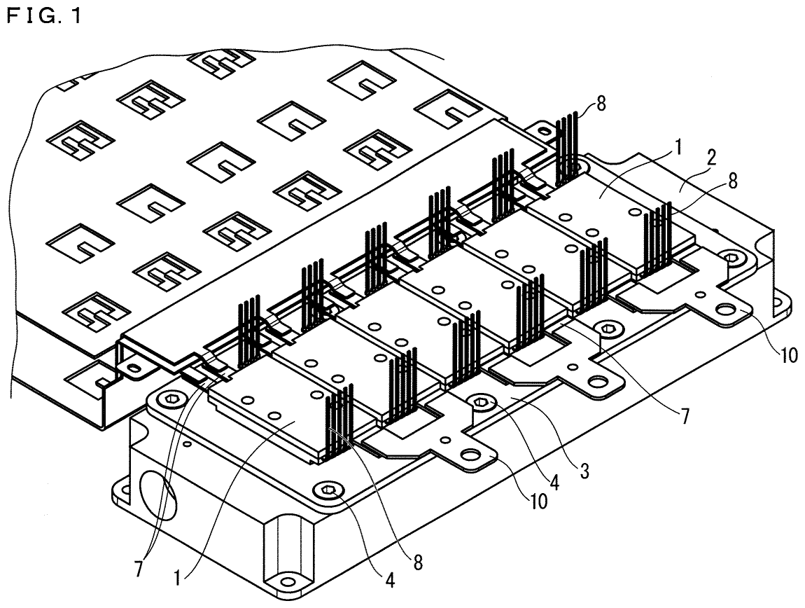

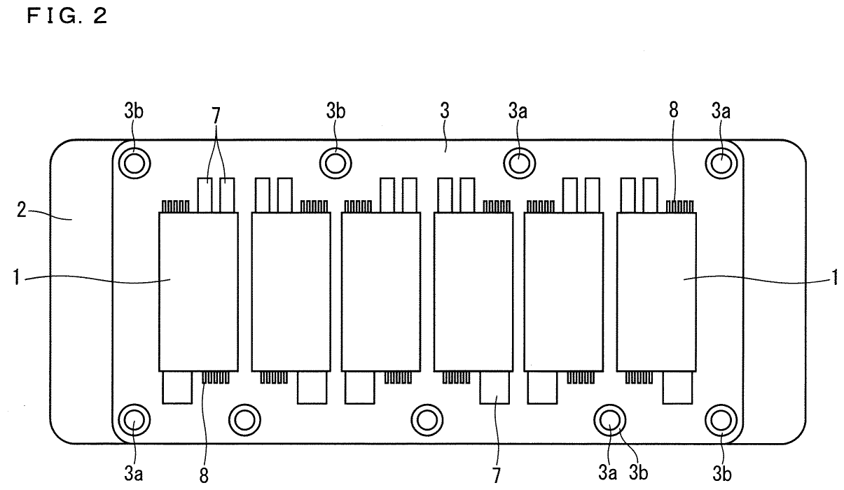

An embodiment 1 is described hereinafter using the diagrams. FIG. 1 is a perspective view of a configuration of a semiconductor unit according to the embodiment 1. FIG. 2 is a top view of the semiconductor unit according to the embodiment 1. FIG. 2 illustrates a state where a screw 4 is detached.

As illustrated in FIG. 1 and FIG. 2, the semiconductor unit includes six semiconductor modules 1, a base plate 3, a cooler 2, and nine screws 4. The semiconductor module 1 is an insulated gate bipolar transistor (IGBT) module, an intelligent power module (IPM), or a transfer-molded power module (T-PM). The semiconductor module 1 includes a semiconductor device (not shown) built in the semiconductor module 1, a plurality of horizontal terminals 7 protruding from a side surface of the semiconductor module 1 in a horizontal direction, and a plurality of control terminals 8 protruding from the side surface of the semiconductor module 1 with a distal end side bended toward an upper side. A bus bar 10, for example, is connected to the horizontal terminal 7.

As illustrated in FIG. 2, distal ends of the plurality of horizontal terminals 7 are located closer to an inner surrounding side in relation to an outer surrounding end of the base plate 3 in a top view. The number of the semiconductor modules 1 is not limited to six, but it is sufficient that one or more semiconductor modules 1 are included.

The semiconductor device is an IGBT or a metal-oxide-semiconductor field-effect transistor (MOSFET), for example. A material constituting the semiconductor device is silicon (Si), for example. A material constituting the semiconductor device is not limited to silicon; however, also applicable is a wide bandgap semiconductor material such as silicon carbide (SiC), gallium nitride (GaN), or diamond (C), for example. It is sufficient that the number of the semiconductor devices is one or more.

The horizontal terminal 7 is electrically connected to the semiconductor device inside the semiconductor module 1. The control terminal 8 is electrically connected to the semiconductor device inside the semiconductor module 1, and transmits a control signal inputted from outside to the semiconductor device.

The base plate 3 is formed into a rectangular shape. Six semiconductor modules 1 are disposed side by side in a long side direction on an upper surface of the base plate 3. Provided is at least a pair of two semiconductor modules 1 to which the horizontal terminal 7 is provided to a position line-symmetric with respect to the long side direction of the base plate 3. Although three pairs of two semiconductor modules 1 are disposed, the configuration is not limited thereto. Each semiconductor module 1 is bonded to the upper surface of the base plate 3 by solder (not shown). A plurality of (nine, for example) screw holes 3a passing through the base plate 3 from the upper surface to a lower surface are provided to an outer surrounding part of the base plate 3. The number of the screw holes 3a is not limited to nine.

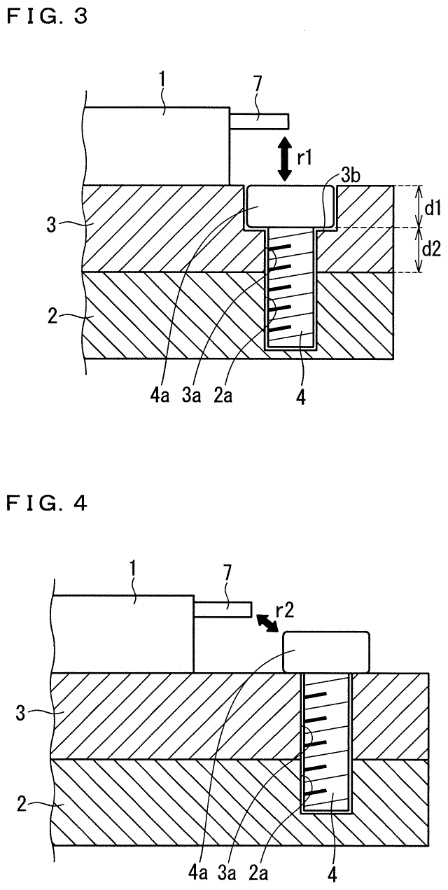

The cooler 2 is attached to the lower surface of the base plate 3 and cools the semiconductor module 1. Nine screw holes 2a (refer to FIG. 3) communicated with nine screw holes 3a, respectively, are provided in positions in the cooler 2 facing nine screw holes 3a of the base plate 3. Since nine screws 4 are screwed to nine screw holes 3a of the base plate 3 and nine screws 2a of the cooler 2, respectively, the cooler 2 is attached to the lower surface of the base plate 3. The screw 4 is a metal screw having conductivity. The screw 4 is also referred to as the conductive screw 4 hereinafter. The cooler 2 is a water cooling system, and a cooling medium (not shown) for cooling the semiconductor module 1 fills inside the cooler 2.

A structure of the screw hole 3a as a characteristic of the embodiment 1 is described next. FIG. 3 is a cross-sectional view of a position where the base plate 3 and the cooler 2 are fastened by the screw and a region around the position according to the embodiment 1.

As illustrated in FIG. 2 and FIG. 3, nine screw holes 3a are provided along an outer surrounding part of the base plate 3. Specifically, nine screw holes 3a are provided to only four corners of the base plate 3 and sides of long sides of the outer surrounding part of the base plate 3. Nine screw holes 3a are not provided in a region in which an interval between the adjacent horizontal terminals 7 is smaller in the adjacent semiconductor modules 1 but are provided to an outer surrounding side of a region in which an interval between the adjacent horizontal terminals 7 is larger.

A spot facing part 3b having a depth smaller than a thickness of the base plate 3 is provided to a part of at least one of nine screw holes 3a on a side of the upper surface of the base plate 3. In the embodiment 1, the spot facing parts 3b are provided to all of the screw holes 3a. The spot facing part 3b is formed to have a larger diameter than a diameter of a head part 4a and a larger depth than a height of the head part 4a so as to be able to house the head part 4a of the screw 4. The spot facing part 3b is formed to have a larger diameter than a diameter of the screw hole 3a of the base plate 3. A depth d1 of the spot facing part 3b is equal to or smaller than 1 mm, and a depth d2 of the screw hole 3a of the base plate 3 is equal to or larger than 2 mm.

Described next is a function effect of the embodiment 1 compared with a case where the spot facing part 3b is not provided to the screw hole 3a illustrated in FIG. 4. FIG. 4 is a cross-sectional view of a position where the base plate 3 and the cooler 2 are fastened by the screw and a region around the position in a case where the spot facing part 3b is not provided to the screw hole 3a.

In FIG. 4, the head part 4a of the screw 4 is located on an upper side than the upper surface of the base plate 3, and when the semiconductor unit is downsized, a distance r2 from the screw 4 to the horizontal terminal 7 gets smaller. Thus, it is difficult to ensure insulation properties between the screw 4 and the horizontal terminal 7. Thus, it is difficult to achieve both ensuring of insulation properties between the screw 4 for attaching the cooler 2 and the horizontal terminal 7 of the semiconductor module 1 and downsizing of the semiconductor unit.

In contrast, in the embodiment 1, the semiconductor unit includes: the semiconductor module 1 including the semiconductor device and the horizontal terminal 7 electrically connected to the semiconductor device and protruding from the side surface in the horizontal direction; the base plate 3 including the upper surface to which the semiconductor module 1 is bonded and the plurality of screw holes 3a passing through the base plate 3 from the upper surface to the lower surface; the cooler 2 attached to the lower surface of the base plate 3 and cooling the semiconductor module 1; and the plurality of screws 4 screwed to the plurality of screw holes 3a of the base plate 3, respectively, so that the cooler 2 is attached to the lower surface of the base plate 3. The spot facing part 3b having the depth smaller than the thickness of the base plate 3 is provided to the part of at least one of the plurality of screw holes 3a on the side of the upper surface of the base plate 3.

Since the head part 4a of the screw 4 is housed in the spot facing part 3b as illustrated in FIG. 3, a distance r1 from the screw 4 to the horizontal terminal 7 is longer than the distance r2 in the case in FIG. 4. Thus, insulation properties between the screw 4 and the horizontal terminal 7 can be ensured. As a result, both ensuring of insulation properties between the screw 4 for attaching the cooler 2 and the horizontal terminal 7 of the semiconductor module 1 and downsizing of the semiconductor unit can be achieved.

Since the distal end of the horizontal terminal 7 is located closer to the inner surrounding side in relation to the outer surrounding end of the base plate 3 in a top view, the plurality of semiconductor units can be disposed close to each other when the semiconductor units are disposed side by side.

When the semiconductor module 1 is the transfer-molded power module, an improvement effect of the insulation properties between the screw 4 for attaching the cooler 2 and the horizontal terminal 7 of the semiconductor module 1 is further increased.

### Embodiment 2

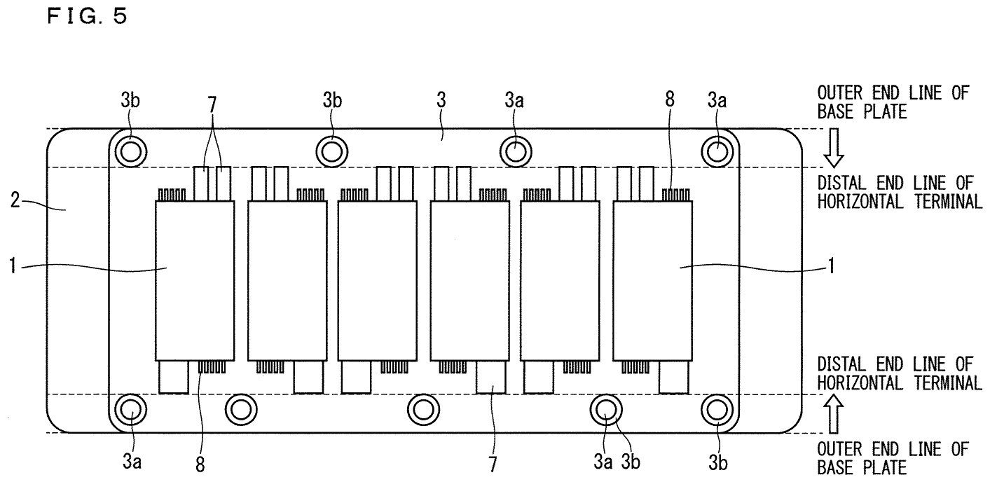

An embodiment 2 is described next. FIG. 5 is a top view of a semiconductor unit according to the embodiment 2. FIG. 5 illustrates a state where the screw 4 is detached. In the description in the embodiment 2, the same reference numerals are assigned to the same constituent elements as those described in the embodiment 1, and the description thereof will be omitted.

As illustrated in FIG. 5, in the embodiment 2, the spot facing part 3b is located closer to an outer surrounding side of the base plate 3 in relation to the distal end of the horizontal terminal 7, and is not overlapped with the horizontal terminal 7 in a top view. In other words, the spot facing part 3b is provided between an outer end line of the base plate 3 and a distal end line of the horizontal terminal 7. The outer end line of the base plate 3 is a line along an outer end of the base plate 3, and the distal end line of the horizontal terminal 7 is a line connecting the distal ends of the plurality of horizontal terminals 7.

In the embodiment 2, since the spot facing part 3b and the horizontal terminal 7 are not overlapped with each other in a top view, the screw 4 can be easily fastened when the cooler 2 is attached to the base plate 3.

### Embodiment 3

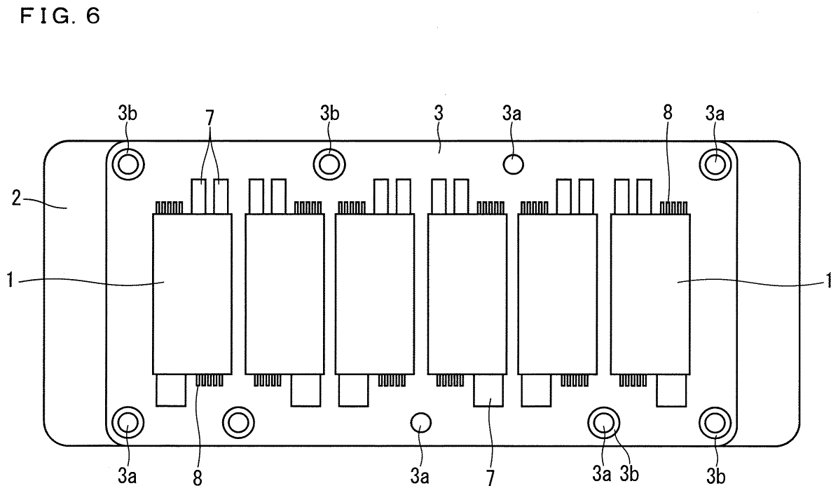

An embodiment 3 is described next. FIG. 6 is a top view of a semiconductor unit according to the embodiment 3. FIG. 6 illustrates a state where the screw 4 is detached. In the description in the embodiment 3, the same reference numerals are assigned to the same constituent elements as those described in the embodiments 1 and 2, and the description thereof will be omitted.

As illustrated in FIG. 6, in the embodiment 3, the spot facing part 3b is not provided to at least one screw hole 3a in nine screw holes 3a. In FIG. 6, the spot facing part 3b is not provided to two screw holes 3a located in a center part in the screw holes 3a provided along the long side direction of the base plate 3.

The screw hole 3a with no spot facing part 3b is provided in the embodiment 3. Since a torque in fastening the screw 4 can be increased compared with the screw hole 3a with the spot facing part 3b, strength of attaching the cooler 2 can be increased.

### Embodiment 4

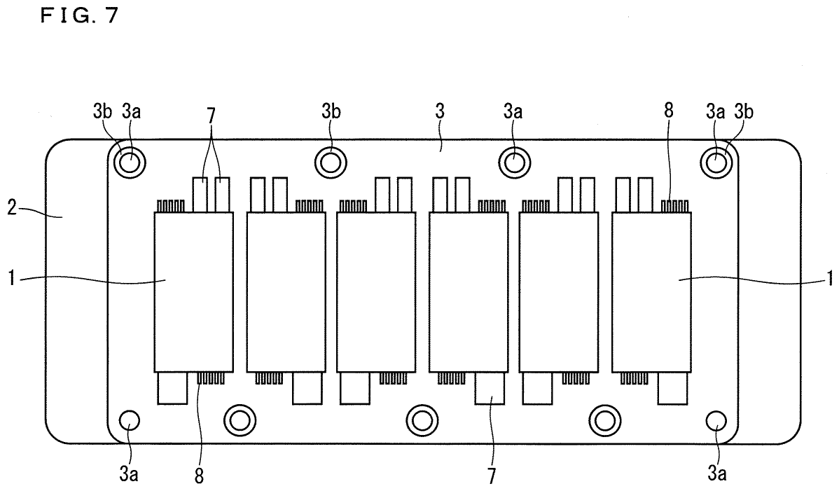

An embodiment 4 is described next. FIG. 7 is a top view of a semiconductor unit according to the embodiment 4. FIG. 7 illustrates a state where the screw 4 is detached. In the description in the embodiment 4, the same reference numerals are assigned to the same constituent elements as those described in the embodiments 1 to 3, and the description thereof will be omitted.

As illustrated in FIG. 7, in the embodiment 4, the spot facing part 3b is not provided to at least one of the screw holes 3a provided to four corners of the base plate 3. Although the spot facing part 3b is not provided to two screw holes 3a in the screw holes 3a provided to four corners of the base plate 3, the configuration is not limited thereto. The spot facing part 3b may not be provided to one or three or more of the screw holes 3a in the screw holes 3a provided to four corners of the base plate 3.

In the embodiment 4, the strength of attaching the cooler 2 can be increased in the manner similar to the embodiment 3.

### Embodiment 5

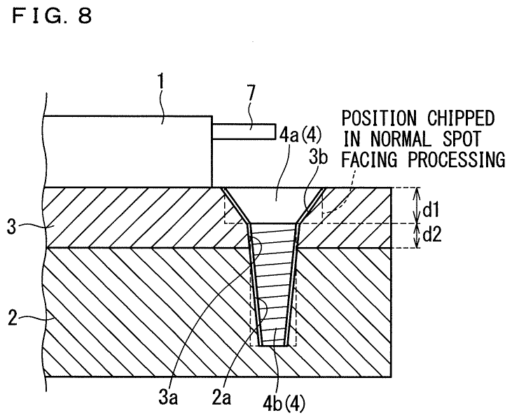

An embodiment 5 is described next. FIG. 8 is a cross-sectional view of a position where the base plate 3 and the cooler 2 are fastened by the screw and a region around the position according to the embodiment 5. In the description in the embodiment 5, the same reference numerals are assigned to the same constituent elements as those described in the embodiments 1 to 4, and the description thereof will be omitted.

As illustrated in FIG. 8, in the embodiment 5, the spot facing part 3b has a tapered shape tapered in a direction from the upper surface of the base plate 3 toward the lower surface thereof. The screw hole 3a of the base plate 3 and the screw hole 2a of the cooler 2 also have a tapered shape tapered in a direction from an upper side toward a lower side. The depth d1 of the spot facing part 3b is equal to or smaller than 1 mm, and the depth d2 of the screw hole 3a of the base plate 3 is equal to or larger than 2 mm. A dot line in FIG. 8 indicates a position chipped in normal spot facing processing.

Each of the head part 4a and a shaft part 4b of the screw 4 also has a tapered shape tapered in a direction from an upper side toward a lower side.

In the embodiment 5, since an amount of chipping the base plate 3 can be reduced compared with the normal spot facing processing, strength of the base plate 3 can be increased. The spot facing part 3b and the head part 4a of the screw 4 can be easily fitted to each other while deviation thereof is suppressed when the screw 4 is screwed to the screw hole 3a.

### Embodiment 6

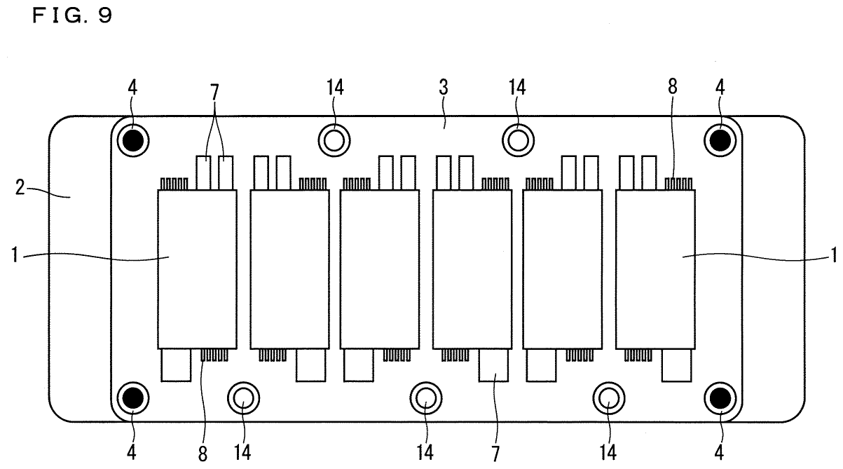

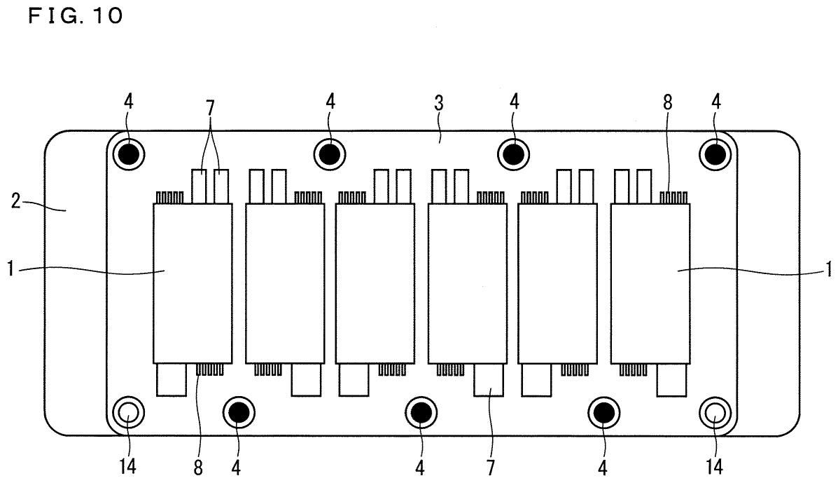

An embodiment 6 is described next. FIG. 9 is a top view of a semiconductor unit according to the embodiment 6. In the description in the embodiment 6, the same reference numerals are assigned to the same constituent elements as those described in the embodiments 1 to 5, and the description thereof will be omitted.

In the embodiments 1 to 5, since the spot facing part 3b is provided to the screw hole 3a, both ensuring of insulation properties between the screw 4 for attaching the cooler 2 and the horizontal terminal 7 of the semiconductor module 1 and downsizing of the semiconductor unit are achieved.

In contrast, as illustrated in FIG. 9, in the embodiment 6, the spot facing part 3b is not provided to the screw hole 3a, but the non-conductive screw 14 is adopted as a screw screwed to the screw hole 3a. Specifically, at least one of the plurality of screws is the non-conductive screw 14. The non-conductive screw 14 is formed into resin having insulation properties, for example.

In FIG. 9, the screws screwed to four corners of the base plate 3 are screws 4 having conductivity, and the other screws are the non-conductive screws 14.

In the embodiment 6, since insulation properties can be ensured regardless of a distance from the non-conductive screw 14 for attaching the cooler 2 to the horizontal terminal 7 of the semiconductor module 1, both ensuring of insulation properties between the non-conductive screw 14 for attaching the cooler 2 and the horizontal terminal 7 of the semiconductor module 1 and downsizing of the semiconductor unit can be achieved without providing the spot facing part 3b.

### Embodiment 7

An embodiment 7 is described next. FIG. 10 is a top view of a semiconductor unit according to the embodiment 7. In the description in the embodiment 7, the same reference numerals are assigned to the same constituent elements as those described in the embodiments 1 to 6, and the description thereof will be omitted.

As illustrated in FIG. 10, a configuration in the embodiment 7 is different from that in the embodiment 6 in that the conductive screw 4 is screwed to at least one of the screw holes 3a provided to four corners of the base plate 3. In FIG. 10, the conductive screw 4 is screwed to two screw holes 3a in the screw holes 3a provided to four corners of the base plate 3.

In the embodiment 7, since some of the screws in four corners of the base plate 3, in which a large load of a torque in fastening the screw is applied, are the conductive screws 4, strength of attaching the cooler 2 can be increased.

### Embodiment 8

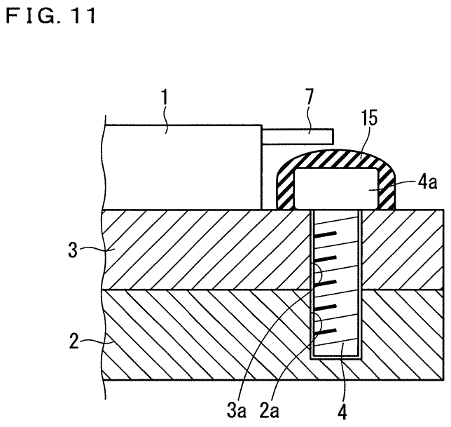

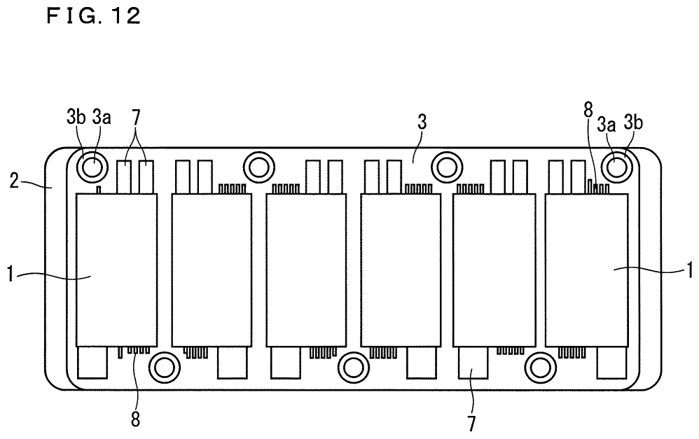

An embodiment 8 is described next. FIG. 11 is a cross-sectional view of a position where the base plate 3 and the cooler 2 are fastened by the screw and a region around the position according to the embodiment 8. In the description in the embodiment 8, the same reference numerals are assigned to the same constituent elements as those described in the embodiments 1 to 7, and the description thereof will be omitted.

In the embodiments 6 and 7, the spot facing part 3b is not provided to the screw hole 3a, but the non-conductive screw 14 is adopted as the screw screwed to the screw hole 3a.

In contrast, as illustrated in FIG. 11, in the embodiment 8, the head part 4a of at least one of the plurality of screws 4 is covered by an insulative resin 15 in place of the non-conductive screw 14.

In the embodiment 8, since insulation properties can be ensured regardless of the distance from the screw 4 for attaching the cooler 2 to the horizontal terminal 7 of the semiconductor module 1 in the manner similar to the embodiment 6, both ensuring of insulation properties between the screw 4 for attaching the cooler 2 and the horizontal terminal 7 of the semiconductor module 1 and downsizing of the semiconductor unit can be achieved without providing the spot facing part 3b.

### Embodiment 9

An embodiment 9 is described next. In the description in the embodiment 9, the same reference numerals are assigned to the same constituent elements as those described in the embodiments 1 to 8, and the description thereof will be omitted.

Although not shown in the diagrams, in the embodiment 9, the screw 4 with the head part 4a covered by the insulative resin 15 is screwed to at least one of the screw holes 3a provided to four corners of the base plate 3.

In the embodiment 9, since some of the screws in four corners of the base plate 3 are the screws 4 covered by the insulative resin 15, a process and cost for covering by the insulative resin 15 can be reduced.

### Embodiment 10

An embodiment 10 is described next. FIG. 12 is a top view of a semiconductor unit according to the embodiment 10. FIG. 12 illustrates a state where the screw 4 is detached. In the description in the embodiment 10, the same reference numerals are assigned to the same constituent elements as those described in the embodiments 1 to 9, and the description thereof will be omitted.

In the embodiments 1 to 9, nine screw holes 3a are provided to only four corners of the base plate 3 and the sides of the long sides of the outer surrounding part of the base plate 3.

In contrast, as illustrated in FIG. 12, in the embodiment 10, seven screw holes 3a are provided to only the sides of the long sides of the outer surrounding part of the base plate 3. Although FIG. 12 illustrates the case where the spot facing part 3b is provided to the screw hole 3a in the embodiments 1 to 5, the configuration in the embodiment 10 can also be adopted to the configurations in the embodiments 6 to 9.

In the embodiment 10, since the screw hole 3a is not provided to a side of a short side of the outer surrounding part of the base plate 3, a size of the base plate 3 in the short side direction can be downsized compared with the case where the screw hole 3a is provided to the side of the short side of the outer surrounding part of the base plate 3. This configuration can lead to further downsizing of the semiconductor unit.

### Embodiment 11

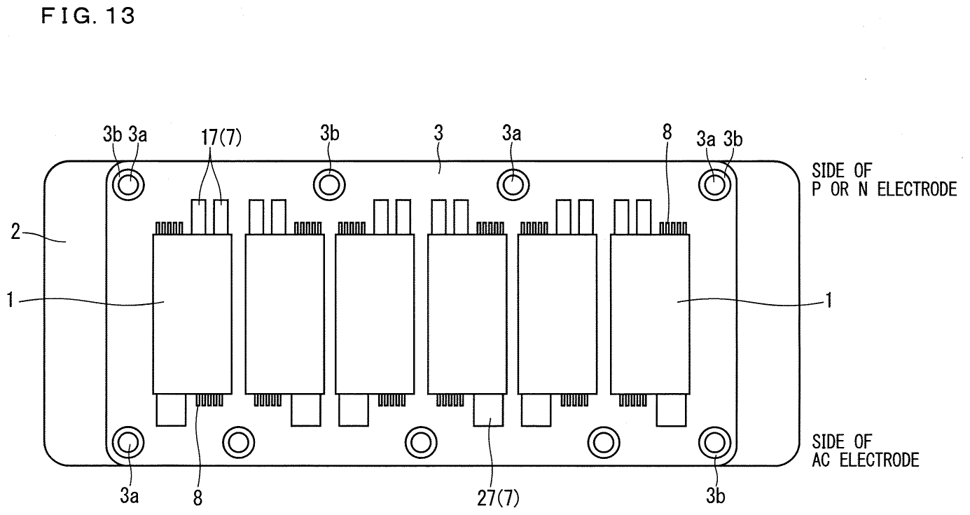

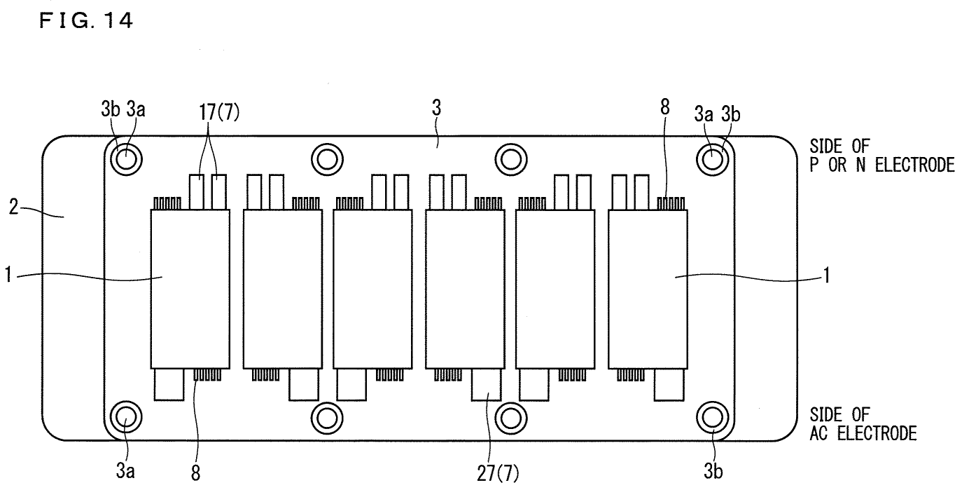

An embodiment 11 is described next. FIG. 13 is a top view of a semiconductor unit according to the embodiment 11. FIG. 14 is a top view of a semiconductor unit in a case where the number of screw holes 3a is the same in a side of a P or N electrodes and a side of an AC electrode. FIGS. 13 and 14 illustrate a state where the screw 4 is detached. In the description in the embodiment 11, the same reference numerals are assigned to the same constituent elements as those described in the embodiments 1 to 10, and the description thereof will be omitted.

As illustrated in FIG. 13, in the embodiment 11, the horizontal terminal 7 includes a first horizontal terminal 17 connected to the P electrode or the N electrode on a side of one long side of the base plate 3 and a second horizontal terminal 27 connected to the A C electrode on a side of the other long side of the base plate 3. In a top view, the first horizontal terminal 17 and the second horizontal terminal 27 protrude from side surfaces in diagonal positions in the semiconductor module 1. In FIG. 13, the side of the P or N electrode is a side on which the terminal is connected to the P electrode or the N electrode, and the side of the AC electrode is a side on which the terminal is connected to the AC electrode. The number of screw holes 3a is different between the side of one long side of the outer surrounding part of the base plate 3 and the other long side thereof. That is to say, the number of screw holes 3a is different between the side of the P or N electrode of the base plate 3 and the side of the AC electrode thereof. The side of the P or N electrode is an upper side in FIG. 13, and the side of the AC electrode is a lower side in FIG. 13. Although FIG. 13 illustrates the case where the spot facing part 3b is provided to the screw hole 3a in the embodiments 1 to 5, the configuration in the embodiment 11 can also be adopted to the configurations in the embodiments 6 to 9.

In the embodiment 11, a degree of freedom can be increased in the arrangement of the screw hole 3a compared with a case where the number of screw holes 3a is the same between the side of the P or N electrode and the side of the AC electrode illustrated in FIG. 14.

### Embodiment 12

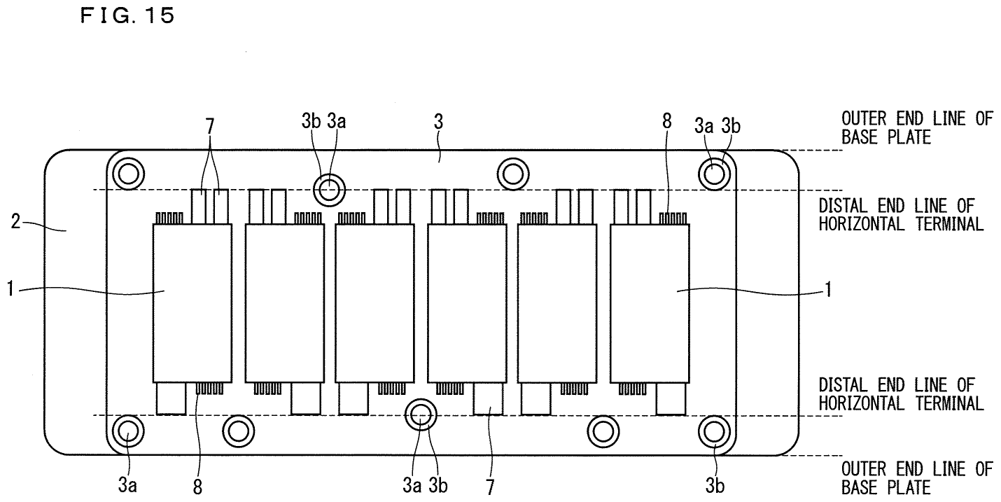

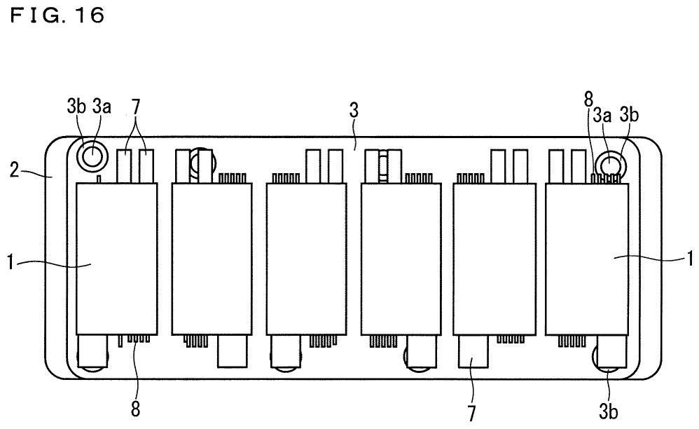

An embodiment 12 is described next. FIG. 15 is a top view of a semiconductor unit according to the embodiment 12. FIG. 15 illustrates a state where the screw 4 is detached. In the description in the embodiment 12, the same reference numerals are assigned to the same constituent elements as those described in the embodiments 1 to 11, and the description thereof will be omitted.

A illustrated in FIG. 15, in the embodiment 12, nine screw holes 3a are partially located closer to the inner surrounding side of the base plate 3 in relation to the horizontal terminal 7 in a top view. Although two screw holes 3a are partially located closer to the inner surrounding side of the base plate 3 in relation to the distal end of the horizontal terminal 7 in FIG. 13, the number of the screw holes 3a partially located closer to the inner surrounding side of the base plate 3 in relation to the distal end of the horizontal terminal 7 is not limited to two. Although FIG. 15 illustrates the case where the spot facing part 3b is provided to the screw hole 3a in the embodiments 1 to 5, the configuration in the embodiment 12 can also be adopted to the configurations in the embodiments 6 to 9.

In the embodiment 12, since the plurality of screw holes 3a are provided to be partially located closer to the inner surrounding side of the base plate 3 in relation to the distal end of the horizontal terminal 7, the semiconductor unit can be downsized.

### Embodiment 13

An embodiment 13 is described next. FIG. 16 is a top view of a semiconductor unit according to the embodiment 13. FIG. 16 illustrates a state where the screw 4 is detached. In the description in the embodiment 13, the same reference numerals are assigned to the same constituent elements as those described in the embodiments 1 to 12, and the description thereof will be omitted.

In the embodiments 1 to 12, nine screw holes 3a are provided to the outer surrounding side of the region in which the interval between the adjacent horizontal terminals 7 is larger in the adjacent semiconductor modules 1.

In contrast, as illustrated in FIG. 16, in the embodiment 13, there is a region in which the horizontal terminal 7 and the plurality of screw holes 3a are overlapped with each other in a top view. In FIG. 16, although six screw holes 3a in eight screw holes 3a and the horizontal terminal 7 are overlapped with each other, and the remaining two screw holes 3a and the control terminal 8 are overlapped with each other in a top view, the number of screw holes 3a overlapped with the horizontal terminal 7 in a top view is not limited thereto. Although FIG. 16 illustrates the case where the spot facing part 3b is provided to the screw hole 3a in the embodiments 1 to 5, the configuration in the embodiment 13 can also be adopted to the configurations in the embodiments 6 to 9.

In the embodiment 13, since the plurality of screw holes 3a are provided to be overlapped with the horizontal terminal 7 in a top view, the semiconductor unit can be downsized.

Each embodiment can be arbitrarily combined, or each embodiment can be appropriately varied or omitted.

The aspects of the present disclosure are collectively described hereinafter as appendixes.

### (Appendix 1)

A semiconductor unit, comprising:
at least one semiconductor module including a semiconductor device and at least one horizontal terminal electrically connected to the semiconductor device and protruding from at least one side surface in a horizontal direction;
a base plate including an upper surface to which the semiconductor module is bonded and a plurality of screw holes passing through the base plate from the upper surface to a lower surface;
a cooler attached to the lower surface of the base plate and cooling the semiconductor module; and
a plurality of screws screwed to the plurality of screw holes of the base plate, respectively, so that the cooler is attached to the lower surface of the base plate, wherein
a spot facing part having a smaller depth than a thickness of the base plate is provided to a part of at least one of the plurality of screw holes on a side of the upper surface of the base plate.

### (Appendix 2)

The semiconductor unit according to Appendix 1, wherein
a distal end of the horizontal terminal is located closer to an inner surrounding side in relation to an outer surrounding end of the base plate in a top view.

### (Appendix 3)

The semiconductor unit according to Appendix 1 or 2, wherein
the spot facing part is located closer to an outer surrounding side of the base plate in relation to the distal end of the horizontal terminal, and is not overlapped with the horizontal terminal in a top view.

### (Appendix 4)

The semiconductor unit according to any one of Appendixes 1 to 3, wherein
the spot facing part is not provided to the at least one of the plurality of screw holes.

### (Appendix 5)

The semiconductor unit according to any one of Appendixes 1 to 4, wherein
the plurality of screw holes include screw holes provided to four corners of the base plate, and
the spot facing part is not provided to the at least one of the screw holes provided to the four corners.

### (Appendix 6)

The semiconductor unit according to any one of Appendixes 1 to 5, wherein
the spot facing part has a tapered shape tapered in a direction from the upper surface toward the lower surface of the base plate.

### (Appendix 7)

A semiconductor unit, comprising:
at least one semiconductor module including a semiconductor device and at least one horizontal terminal electrically connected to the semiconductor device and protruding from at least one side surface in a horizontal direction;
a base plate including an upper surface to which the semiconductor module is bonded and a plurality of screw holes passing through the base plate from the upper surface to a lower surface;
a cooler attached to the lower surface of the base plate and cooling the semiconductor module; and
a plurality of screws screwed to the plurality of screw holes of the base plate, respectively, so that the cooler is attached to the lower surface of the base plate, wherein
at least one of the plurality of screws is a non-conductive screw.

### (Appendix 8)

The semiconductor unit according to Appendix 7, wherein
the plurality of screw holes include screw holes provided to four corners of the base plate, and
a conductive screw is screwed to at least one of the screw holes provided to the four corners.

### (Appendix 9)

A semiconductor unit, comprising:
at least one semiconductor module including a semiconductor device and at least one horizontal terminal electrically connected to the semiconductor device and protruding from at least one side surface in a horizontal direction;
a base plate including an upper surface to which the semiconductor module is bonded and a plurality of screw holes passing through the base plate from the upper surface to a lower surface;
a cooler attached to the lower surface of the base plate and cooling the semiconductor module; and
a plurality of screws screwed to the plurality of screw holes of the base plate, respectively, so that the cooler is attached to the lower surface of the base plate, wherein
a head part of at least one of the plurality of screws is covered by insulative resin.

### (Appendix 10)

The semiconductor unit according to Appendix 9, wherein
the plurality of screw holes include screw holes provided to four corners of the base plate, and
the screw with the head part covered by the insulative resin is screwed to at least one of the screw holes provided to the four corners.

### (Appendix 11)

The semiconductor unit according to any one of Appendixes 1 to 10, wherein
the base plate is formed into a rectangular shape, and
the plurality of screw holes are provided to only sides of long sides of an outer surrounding part of the base plate.

### (Appendix 12)

The semiconductor unit according to Appendix 11, wherein
a total number of the screw holes is different between one of the sides of the long sides and another one of the sides of the long sides of the outer surrounding part of the base plate.

### (Appendix 13)

The semiconductor unit according to Appendix 12, comprising
the plurality of semiconductor modules, wherein
the plurality of semiconductor modules are disposed side by side in a long side direction of the base plate, and
the horizontal terminal includes a first horizontal terminal connected to a P electrode or an N electrode on one of the sides of the long sides of the base plate and a second horizontal terminal connected to an A C electrode on another one of the sides of the long sides of the base plate.

### (Appendix 14)

The semiconductor unit according to Appendix 13, wherein
provided is at least a pair of the two semiconductor modules to which the horizontal terminal is provided to a position line-symmetric with respect to the long side direction of the base plate side by side in the long side direction of the base plate, and
the plurality of screw holes are provided to an outer surrounding side of a region in which an interval between the horizontal terminals adjacent to each other is larger in the semiconductor modules adjacent to each other.

### (Appendix 15)

The semiconductor unit according to Appendix 13, wherein
in a top view, the first horizontal terminal and the second horizontal terminal protrude from the side surfaces in diagonal positions in the semiconductor module.

### (Appendix 16)

The semiconductor unit according to Appendix 13, wherein
in a top view, the semiconductor module further includes control terminals protruding from the side surfaces in diagonal positions in the semiconductor module with a distal end side bended toward an upper side to transmit a control signal.

### (Appendix 17)

The semiconductor unit according to any one of Appendixes 1 to 16, wherein
in a top view, the plurality of screw holes are partially located closer to an inner surrounding side of the base plate in relation to a distal end of the horizontal terminal.

### (Appendix 18)

The semiconductor unit according to any one of Appendixes 1 to 16, wherein
in a top view, there is a region in which the horizontal terminal and the plurality of screw holes are overlapped with each other.

### (Appendix 19)

The semiconductor unit according to any one of Appendixes 1 to 18, wherein
the semiconductor module is a transfer-molded semiconductor module.

While the disclosure has been shown and described in detail, the foregoing description is in all aspects illustrative and not restrictive. It is therefore understood that numerous modifications and variations can be devised.

What is claimed is:

1. A semiconductor unit, comprising:
at least one semiconductor module including a semiconductor device and at least one horizontal terminal electrically connected to the semiconductor device and protruding from at least one side surface in a horizontal direction;
a base plate including an upper surface to which the semiconductor module is bonded and a plurality of screw holes passing through the base plate from the upper surface to a lower surface;
a cooler attached to the lower surface of the base plate and cooling the semiconductor module; and
a plurality of screws screwed to the plurality of screw holes of the base plate, respectively, so that the cooler is attached to the lower surface of the base plate, wherein
a spot facing part having a smaller depth than a thickness of the base plate is provided to a part of at least one of the plurality of screw holes on a side of the upper surface of the base plate.

2. The semiconductor unit according to claim 1, wherein
a distal end of the horizontal terminal is located closer to an inner surrounding side in relation to an outer surrounding end of the base plate in a plan view.

3. The semiconductor unit according to claim 1, wherein
the spot facing part is located closer to an outer surrounding side of the base plate in relation to the distal end of the horizontal terminal, and is not overlapped with the horizontal terminal in a top view.

4. The semiconductor unit according to claim 1, wherein
the spot facing part is not provided to the at least one of the plurality of screw holes.

5. The semiconductor unit according to claim 1, wherein
the plurality of screw holes include screw holes provided to four corners of the base plate, and
the spot facing part is not provided to the at least one of the screw holes provided to the four corners.

6. The semiconductor unit according to claim 1, wherein
the spot facing part has a tapered shape tapered in a direction from the upper surface toward the lower surface of the base plate.

7. A semiconductor unit, comprising:
at least one semiconductor module including a semiconductor device and at least one horizontal terminal electrically connected to the semiconductor device and protruding from at least one side surface in a horizontal direction;
a base plate including an upper surface to which the semiconductor module is bonded and a plurality of screw holes passing through the base plate from the upper surface to a lower surface;
a cooler attached to the lower surface of the base plate and cooling the semiconductor module; and
a plurality of screws screwed to the plurality of screw holes of the base plate, respectively, so that the cooler is attached to the lower surface of the base plate, wherein
at least one of the plurality of screws is a non-conductive screw.

8. The semiconductor unit according to claim 7, wherein
the plurality of screw holes include screw holes provided to four corners of the base plate, and
a conductive screw is screwed to at least one of the screw holes provided to the four corners.

9. A semiconductor unit, comprising:
at least one semiconductor module including a semiconductor device and at least one horizontal terminal electrically connected to the semiconductor device and protruding from at least side surface in a horizontal direction;
a base plate including an upper surface to which the semiconductor module is bonded and a plurality of screw holes passing through the base plate from the upper surface to a lower surface;
a cooler attached to the lower surface of the base plate and cooling the semiconductor module; and
a plurality of screws screwed to the plurality of screw holes of the base plate, respectively, so that the cooler is attached to the lower surface of the base plate, wherein
a head part of at least one of the plurality of screws is covered by insulative resin.

10. The semiconductor unit according to claim 9, wherein
the plurality of screw holes include screw holes provided to four corners of the base plate, and
the screw with the head part covered by the insulative resin is screwed to at least one of the screw holes provided to the four corners.

11. The semiconductor unit according to claim 1, wherein
the base plate is formed into a rectangular shape, and
the plurality of screw holes are provided to only sides of long sides of an outer surrounding part of the base plate.

12. The semiconductor unit according to claim 11, wherein
a total number of the screw holes is different between one of the sides of the long sides and another one of the sides of the long sides of the outer surrounding part of the base plate.

13. The semiconductor unit according to claim 12, comprising
the plurality of semiconductor modules, wherein
the plurality of semiconductor modules are disposed side by side in a long side direction of the base plate, and
the horizontal terminal includes a first horizontal terminal connected to a P electrode or an N electrode on one of the sides of the long sides of the base plate and a second horizontal terminal connected to an A C electrode on another one of the sides of the long sides of the base plate.

14. The semiconductor unit according to claim 13, wherein
provided is at least a pair of the two semiconductor modules to which the horizontal terminal is provided to a position line-symmetric with respect to the long side direction of the base plate side by side in the long side direction of the base plate, and
the plurality of screw holes are provided to an outer surrounding side of a region in which an interval between the horizontal terminals adjacent to each other is larger in the semiconductor modules adjacent to each other.

15. The semiconductor unit according to claim 13, wherein
in a top view, the first horizontal terminal and the second horizontal terminal protrude from the side surfaces in diagonal positions in the semiconductor module.

16. The semiconductor unit according to claim 13, wherein
in a top view, the semiconductor module further includes control terminals protruding from the side surfaces in diagonal positions in the semiconductor module with a distal end side bended toward an upper side to transmit a control signal.

17. The semiconductor unit according to claim 1, wherein
in a top view, the plurality of screw holes are partially located closer to an inner surrounding side of the base plate in relation to a distal end of the horizontal terminal.

18. The semiconductor unit according to claim 1, wherein
in a top view, there is a region in which the horizontal terminal and the plurality of screw holes are overlapped with each other.

19. The semiconductor unit according to claim 1, wherein
the semiconductor module is a transfer-molded semiconductor module.
